(19) United States
(12) Patent Application Publication
(10) Pub. No.: US 2002/0185742 A1
(43) Pub. Date: Dec. 12, 2002

(54) Semiconductor device and method of manufacturing the same

(76) Inventors: Atsushi Ootake, Hitachi (JP); Kinya Kobayashi, Hitachi (JP)

Correspondence Address: DICKSTEIN SHAPIRO MORIN & OSHINSKY LLP, 2101 L STREET NW, WASHINGTON, DC, 20037-1526, US

(21) Appl. No.: 10/192,540

(22) Filed: Jul. 11, 2002

Related U.S. Application Data
(62) Division of application No. 10/067,214, filed on Feb. 7, 2002.

(30) Foreign Application Priority Data
Jun. 5, 2001 (JP) 2001-169544

(51) Int. Cl. H01L 21/336; H01L 23/48; H01L 29/40

(52) U.S. Cl. 257/776; 257/752; 257/750; 257/784; 438/652; 438/626; 438/619; 438/280

(57) ABSTRACT

An object of the present invention is to provide a semiconductor device and a method of manufacturing the semiconductor device which can improve the flatness after the chemical mechanical polishing by inserting necessary and minimum dummy patterns and has high throughput.

The present invention is characterized by a semiconductor device is flattened through a chemical mechanical polishing method, wherein the surface of the semiconductor element is virtually divided into a plurality of areas, and the wiring necessary for circuit operation and a dummy pattern of the wiring unnecessary for the circuit operation are formed so as to satisfy at least one out of conditions that differences among ratios occupied by convex areas or by concave areas in the individual virtual divided areas may be smaller than 10%; and that a ratio of the maximum value to the minimum value among the ratios occupied by the convex areas or by the concave areas in the individual virtual divided areas may be smaller than 1.3; and that a difference between the maximum height and the minimum height in each of the virtual divided areas may be smaller than 30 nm.

### BACKGROUND OF THE INVENTION

The present invention relates to a semiconductor device and a method of manufacturing the semiconductor device, and particularly to a semiconductor device in which a thin film formed on a semiconductor wafer is flatted through a chemical mechanical polishing method (hereinafter, referred to as a CMP method).

The minimum processing dimension of the semiconductor device is being scaled down as the integration degree is being improved. With the above, the depth of focus at photo-mask exposing becomes shallow, and accordingly micro-unevenness on the surface of a semiconductor device is a problem of the light exposure. Further, in order to prevent occurrence of wire breaking failure caused by unevenness of each layer of the semiconductor device (multi-layered integrated circuit element), the surface of a semiconductor device is required to be highly flat. In order to cope with the requirement, surface steps of an insulation film and a metallic thin film formed on a pattern are usually flattened through the CMP method. In the CMP method, polishing rate is different between a portion having a dense convex pattern (dense wiring pattern portion and the like) and a portion having a thin convex pattern.

Therefore, when a convex pattern distribution is non-uniform, there is a possibility that unevenness remains in the surface polished shape after polishing, and the wafer can not be flattened. In order to solve this problem, a method is employed. The method is that the convex pattern distribution is made uniform on the basis of chip or wafer by introducing a not-electrically-functioning convex pattern (hereinafter, referred to as dummy pattern) to a portion having a thin convex pattern. There are the following published references relating the dummy pattern aiming at improving the CMP polishing uniformity.

(1) Japanese Patent Application Laid-Open No.2000-114258 discloses a method of making an overall convex pattern distribution uniform to improve the polishing flatness by cyclically arranging a dummy pattern of a given shape in an area having a thin circuit pattern, and then introducing a dummy pattern of an arbitrary shape between circuit patterns in an area where the dummy pattern of the given shape is not introduced.

(2) Japanese Patent Application Laid-Open No.2000-138218 discloses a method of improve the polishing uniformity by forming a dummy pattern in a scribe area.

(3) Japanese Patent Application Laid-Open No.2000-294557, Japanese Patent Application Laid-Open No.2000-21882 and Japanese Patent Application Laid-Open No.11-45868 disclose methods of improve the polishing uniformity of a product chip by forming a dummy pattern equal to a pattern of the product or having a density approximately equal to a density of the patter the product in the outside of the product chips formed on a wafer.

Each of the published references described above aims at improvement of CMP flatness by introducing the dummy pattern into semiconductor device.

In the published reference (1), since it is necessary to find a gap between circuit patterns and to insert the arbitrary dummy pattern shape into the gap, a large amount of work and calculations are required in the case of an actual semiconductor device (memory, processor and so on) having many circuit patterns. Further, since an amount of inserted dummy patterns is increased to increase the convex areas as a whole, the electric characteristics of the circuit may be deteriorated and the CMP time is increased to deteriorate the throughput at manufacturing.

In the published reference (2), since the dummy patterns are introduced only the scribe area in the peripheral portion of a chip, it is difficult to improve the flatness in a recent semiconductor device product in which width of the scribe area is only hundreds nm at the maximum. Further, the effect may be reduced when the chip size becomes large (above 10 mm).

In the published reference (3), it is possible to improve the flatness of the semiconductor chips existing in the peripheral portion of a wafer, but it is impossible to improve the flatness of the semiconductor chips existing in the central portion of the wafer.

### SUMMARY OF THE INVENTION

An object of the present invention is to provide a semiconductor device and a method of manufacturing the semiconductor device which can improve the flatness after the chemical mechanical polishing by inserting necessary and minimum dummy patterns and has high throughput.

The present invention is characterized by a semiconductor device of which an insulation layer covering wiring formed on a surface of a semiconductor element is flattened through a chemical mechanical polishing method, wherein the surface of the semiconductor element is virtually divided into a plurality of areas, and the wiring necessary for circuit operation and a dummy pattern of the wiring unnecessary for the circuit operation are formed so as to satisfy at least one out of conditions that differences among ratios occupied by convex areas or by concave areas in the individual virtual divided areas may be smaller than 10%, preferably 0.5 to 5%; and that a ratio of the maximum value to the minimum value among the ratios occupied by the convex areas or by the concave areas in each of the virtual divided areas may be smaller than 1.3, preferably 1.0 to 1.25; and that a difference between the maximum height and the minimum height in each of the virtual divided areas may be smaller than 30 nm, preferably 5 to 20 nm.

That is, the present invention is that the surface of the semiconductor element to be polished is virtually divided into a plurality of areas; and the wiring necessary for circuit operation and the dummy pattern of the wiring unnecessary for the circuit operation are formed based on at least one out of differences among the ratios of area, and a ratio of the maximum value to the minimum value among the ratios of area occupied by the convex areas or by the concave areas in the individual virtual divided areas, and a difference between the maximum height and the minimum height in each of the virtual divided areas. In other words, the wiring unnecessary for the circuit operation is formed and arranged on the surface of the semiconductor element by adding to the wiring necessary for the circuit operation so that the ratios of the convex areas or the concave areas in the individual virtual divided areas may approach to a value, that is, the differences among the ratios occupied by the convex areas or the concave areas in the individual virtual divided areas may become smaller than a specified value.

It is preferable that the surface of the semiconductor element is made of a single material, and an area of the virtual divided area is made equal to an area of a circle expressed by a radius Rc [mm] by polishing a substrate, on which a plurality of line-shaped grooves having a width A [mm] are engraved with a gap B [mm] between the grooves, using a chemical mechanical polishing apparatus, where the Rc [mm] is a value of the B [mm] when a polishing rate becomes ½ of the maximum polishing rate obtained by varying magnitudes of the A and B while a ratio of the A/B is being kept constant.

Using the Rc described above, the initial polishing rate γ(r0) at a point r0 can be expressed as follows.

$$γ ( r0 ) ∝ K / ρ ( r0 ) \\ ρ ( r0 ) = {\sum }_{r = r0}^{r0 + Rc} \{ F ( r ) ( ρ0 ( r ) \} / {\sum }_{r = r0}^{r0 + Rc} \{ F ( r ) \} \qquad [ Equation 1 ]$$

γ(r0): a polishing rate at a point r0 on a wafer with a pattern

K: a polishing rate of a wafer without any pattern [mm/s]

ρ(r0): an average value of convex portion areal ratio in an area within a radius Rc [mm] from the point r0

ρ0(r): a convex portion areal ratio at a point r

F(r): an averaging weighting function (a parabolic function, a quadratic function or the like)

In a simple approximation, the dispersion of polishing rate distribution can be suppressed by dividing the surface of the semiconductor device into square areas having the same area as an area of a circle expressed by the radius Rc and by making the ratios of the convex areas (or the concave areas) in the individual divided areas close to one another.

It is preferable that the surface of the semiconductor element to be polished is divided into square areas having a side length L [mm] smaller than said Rc×√π [mm]; and ratios of convex areas on said surface of the semiconductor element in the individual virtual divided areas are calculated; and the dummy pattern different from the divided area to the divided area is inserted into the divided areas other than a divided area having the maximum ratio of the convex area so that a value of the maximum value of the ratio occupied by the convex areas divided by the ratio occupied by the convex areas in the individual virtual divided areas may be smaller than a value q.

The CMP polishing rate at the point r0 on the surface of the semiconductor device is influenced by the ratio of the convex area at each point within a range of the radius Rc [mm] from the point r0 (the convex portion areal ratio, ρ(r), r0≦r≦Rc).

$$γ ( r0 ) ∝ K / ρ ( r0 ) \\ ρ ( r0 ) = {\sum }_{r = r0}^{r0 + Rc} \{ F ( r ) ( ρ0 ( r ) \} / {\sum }_{r = r0}^{r0 + Rc} \{ F ( r ) \} \qquad [ Equation 2 ]$$

γ(r0): a polishing rate at a point r0 on a wafer with a pattern

K: a polishing rate of a wafer without any pattern [mm/s]

ρ(r0): an average value of convex portion areal ratio in an area within a radius Rc [mm] from the point r0

ρ0(r): a convex portion areal ratio at a point r

F(r): an averaging weighting function (a parabolic function, a quadratic function or the like)

Therein, in the case where the circle having the radius Rc is converted to a square having the same area, a side of the square becomes d (=Rc√). The average value of the convex portion areal ratio ρ(r0) can be approximated by averaging the convex portion areal ratio ρ0 within the square having the side d [mm] and the center of the point r0 instead of averaging within the circle from r0 to the radius Rc, and a point placed at every d [mm] in the vertical and horizontal directions of the semiconductor device is used as a representative value of the areal ratio for each d [mm] square surrounding the point. The calculation accuracy of the areal ratio is increased as the value d is set to a smaller value. Therefore, the surface of the semiconductor device may be divided by a value L [mm] smaller than d [mm]. By inserting the dummy pattern into each of the divided areas so that the convex portion areal ratios become equal to one another, the whole convex portion areal ratios are uniformed, and accordingly the polishing rates are almost equalized. Further, since the dummy patter is inserted into each of the divided area so as to agree with the maximum value of the convex portion areal ratio before inserting the dummy pattern, the flatting can be attained with a minimum necessary amount of dummy insertion.

It is preferable in the means described above to provide a method of manufacturing a semiconductor device characterized by that the semiconductor device is a semiconductor chip formed on the wafer. By optimizing the dummy pattern for each semiconductor chip, the calculation load can be reduced and the amount of work necessary for forming a mask can be reduced.

It is preferable in the means described above to provide a method of manufacturing a semiconductor device characterized by that the semiconductor device is the whole wafer on which semiconductor chips are formed. Thereby, it is possible to flattening a wafer having various kinds of chips, and at the same time flatness of chips existing in the peripheral portion of the wafer can be improved.

It is preferable to provide in the means described above a method of manufacturing a semiconductor device characterized by that the value of L is larger than 0.5 mm and smaller than 5.0 mm. The value Rc described above becomes a value of approximately 1 mm to 3 mm in the general CPM polishing condition. It is possible to realize flatness of a surface of the semiconductor device in a range of L<d where d=Rc√.

It is preferable in the means described above to provide a method of manufacturing a semiconductor device characterized by that the value of q is smaller than 1.3. Thereby, it is possible to certainly realize the effect of improving the flatness by introducing the dummy pattern.

It is preferable in the means described above that the divided area is a rectangular area having a shorter side M [mm] and a longer side N [mm]. Thereby, the effect of flattening can be obtained by introducing the minimum amount of the dummy pattern similarly to the case of the square divided areas using L [mm].

It is preferable in the means described above that when a plurality of wafers are successively single-wafer processed using a single CMP processing apparatus, the value L [mm] is varied among the plurality of wafers. The value Rc is sometimes increased (or decreased) while the CMP processing is repeated using a single CMP polishing pad. Therefore, it is possible to obtain high flatness irrespective of number of processing times by varying the value L [mm] corresponding to the number of processing times in advance.

The dummy pattern means a dummy transistor, a dummy signal wiring layer and so on. The virtual area is preferably divided into 9, 25, 49 sections to one semiconductor device.

### BRIEF DESCRIPTION OF THE DRAWINGS

FIG. 1 is a diagram showing areal ratios occupied by convex portions of a semiconductor device in accordance with the present invention.

FIG. 2 is a plan view showing grooves formed in a TEOS oxide film on an Si substrate.

FIG. 3 is a graph showing the relationship between remaining film height (max-min)/2 and width of groove.

FIG. 4 is a view showing a semiconductor devices scribed on a wafer.

FIG. 5 is a flowchart showing a method of manufacturing a semiconductor device in accordance with the present invention.

FIG. 6 is a cross-sectional view showing a wiring layer of a semiconductor device in accordance with the present invention.

FIG. 7 is a plan view showing the wiring layer of the semiconductor device in accordance with the present invention.

FIG. 8 is a plan view showing the wiring layer of the semiconductor device in accordance with the present invention.

FIG. 9 is a diagram showing areal ratios occupied by convex portions of a semiconductor device in accordance with the present invention.

FIG. 10 is a flowchart showing a method of manufacturing a semiconductor device in accordance with the present invention.

FIG. 11 is a plan view showing forming of dummy patterns of a semiconductor device in accordance with the present invention.

FIG. 12 is a flowchart showing a method of manufacturing a semiconductor device in accordance with the present invention.

FIG. 13 is a plan view showing a wafer on which different kinds of semiconductor devices are formed.

FIG. 14 is a graph showing the relationship between remaining film height (max-min)/2 and width of groove.

FIG. 15 is a graph showing the relationship between Rc and number of processing times of a semiconductor device in accordance with the present invention.

### PREFERRED EMBODIMENTS OF THE INVENTION

(Embodiment 1)

A method of manufacturing a semiconductor device in accordance with the present invention will be described below. Therein, the object to be polished is a semiconductor device of 10 mm×10 mm square, and an ozone-TEOS oxide film is deposited on the surface of its wiring, and many convex patterns are formed along the wires on the surface of the O₃-TEOS oxide film. The area of 10 mm×10 mm is divided into 9 squares having a side of 3.33 mm.

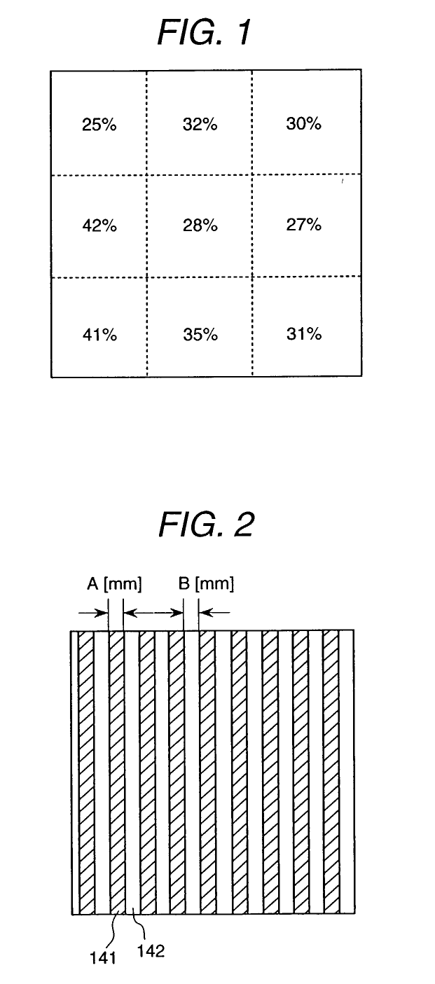

FIG. 1 shows ratios of areas occupied by convex portions (convex portion areal ratios) in the divided areas. It can be understood from FIG. 1 that the distribution of the convex areas is 25 to 42%, that is, the difference is as large as 17%. The pattern was CMP polished, which resulted a polishing height difference of ±36 nm. Then, the convex patterns were rearranged so that the areal ratios of the nine convex areas were within 31% to 32.5%. As the result, the height difference after the CMP polishing could be suppressed to ±20 mm, and the flatness of the semiconductor device could be improved.

(Embodiment 2)

Description will be made below on a case where the divided areas are determined based on the characteristic length Rc obtained from the test in Embodiment 1.

FIG. 2 shows an Si substrate on which an ozone-TEOS oxide film of 1000 nm thick is deposited and grooves 141 of 500 nm depth and A [mm] width are formed in a B [mm] spacing 142. By preparing various kinds substrates on which grooves were formed by varying B from 0.1 mm to 3 mm while the ratio A/B was being kept to 0.4/0.6, and initial (a period of 20 seconds after starting the polishing) polishing rates were measured from polishing the substrates.

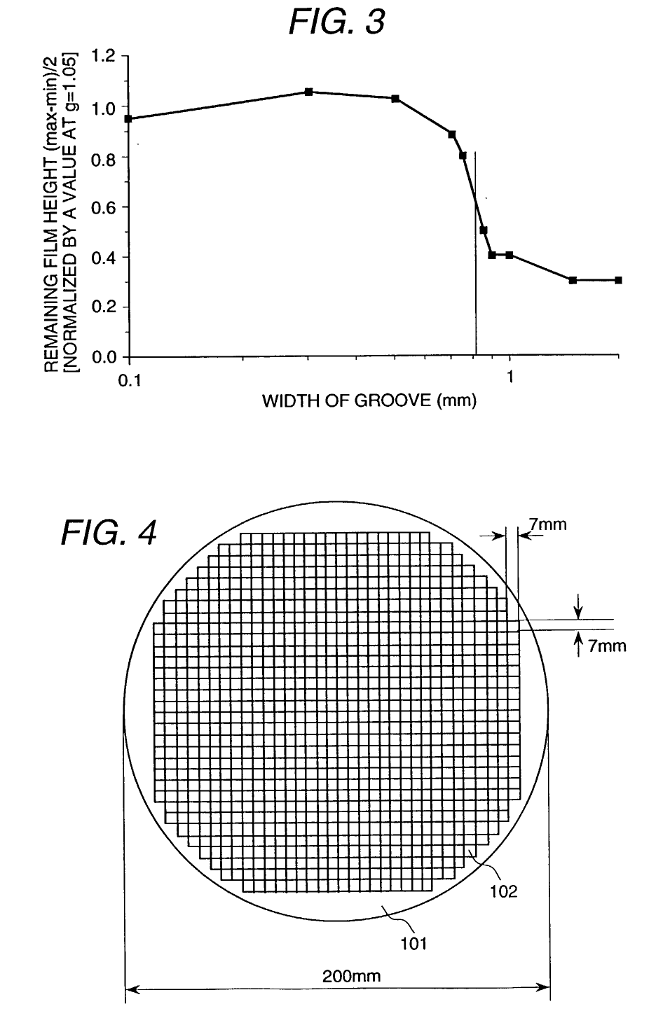

FIG. 3 shows the polishing rates plotted to the width of the groove B [mm]. It can be understood from FIG. 3 that the polishing rate little changes when B is small and rapidly decreases to ½ of the maximum value at B=0.8 mm when B is being increased. This phenomenon means that a given point in the CMP polishing pad is influenced by a convex-and-concave effect at a point up to 0.8 mm distant from the given point as the center. Letting the value of 0.8 mm be Rc, the initial polishing rate γ(r0) can be expressed as the following with respect to the given point as the center.

$$γ ( r0 ) ∝ K / ρ ( r0 ) \\ ρ ( r0 ) = {\sum }_{r = r0}^{Rc} \{ F ( r ) ( ρ0 ( r ) \} / {\sum }_{r = r0}^{Rc} \{ F ( r ) \} \qquad [ Equation 3 ]$$

γ(r0): a polishing rate at a point r0 on a wafer with a pattern

K: a polishing rate of a wafer without any pattern [mm/s]

ρ(r0): an average value of convex portion areal ratio in an area within a radius Rc [mm] from the point r0

ρ0(r): a convex portion areal ratio at a point r

F(r): an averaging weighting function (a parabolic function, a quadratic function or the like)

In a simple approximation, the dispersion of polishing rate distribution can be suppressed by dividing the surface of the semiconductor device into areas having the same area as an area of a circle expressed by the radius Rc and by making the ratios of the convex areas (or the concave areas) in the individual divided areas close to one another.

In a case where the surface is divided into square areas, a square having the same area as that of the circle having a radius Rc (=0.8 mm) can be converted to a square having a side of 1.417 mm. In a case where a semiconductor device of 10 mm square is divided by a square of 1.417 mm side, the surface of the semiconductor device is divided into 49 areas (7×7 areas). In the case where rearrangement of convex patterns was performed by dividing the semiconductor device into 49 divisions in Embodiment 1, the polishing height difference after PMC processing could be suppressed within ±15 nm.

(Embodiment 3)

An embodiment of a method of manufacturing semiconductor devices in accordance with the present invention will be described below, referring to FIG. 4 to FIG. 11.

There, the object to be polished is a wafer 101 of 200 mm diameter shown in FIG. 4, and semiconductor chips 102 of 7 mm square are spread all over the wafer 101 to be exposed. Further, the layer to be polished is an ozone-TEOS (tetra ethyl ortho silicate) oxide film formed on an aluminum wiring layer. The whole wafer is comprised of semiconductor chips 102 of the same type, and flatness of the whole wafer 101 can be improved by increasing flatness of each of the semiconductor chips 102.

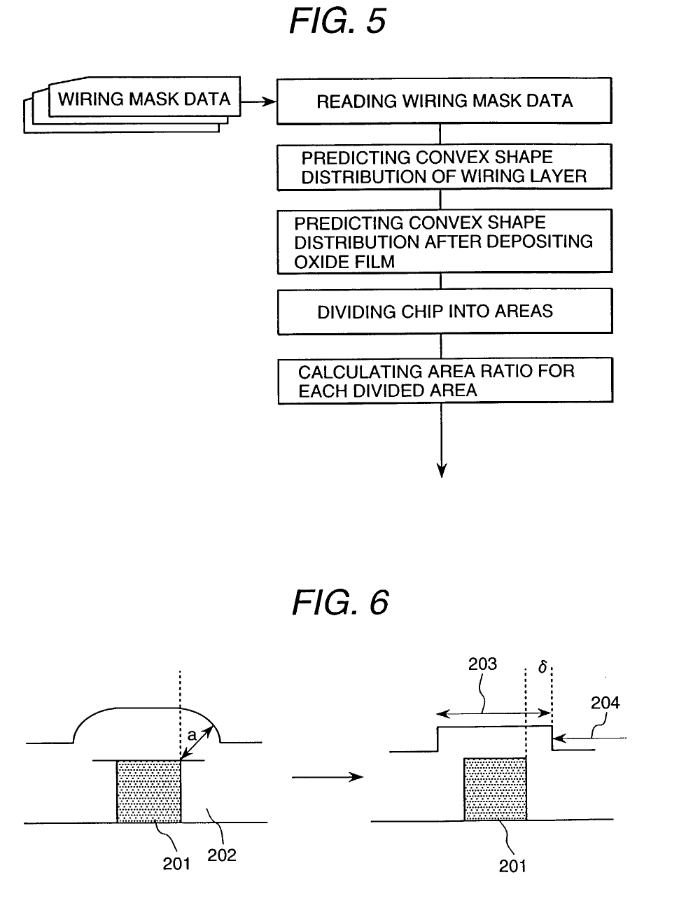

The following procedure is executed according to the flowchart of FIG. 5. In the case of forming the ozone-TEOS oxide film on the aluminum wiring layer, calculation processing on what convex shape distribution appears is initially executed. First, a convex shape distribution of the aluminum layers is calculated by reading mask data on the aluminum wiring layer. In the case of an aluminum wiring layer, convex shaped portions are portions where the aluminum wires exist. Next, a convex shape distribution after depositing the ozone-TEOS oxide film on the aluminum wiring layer is calculated.

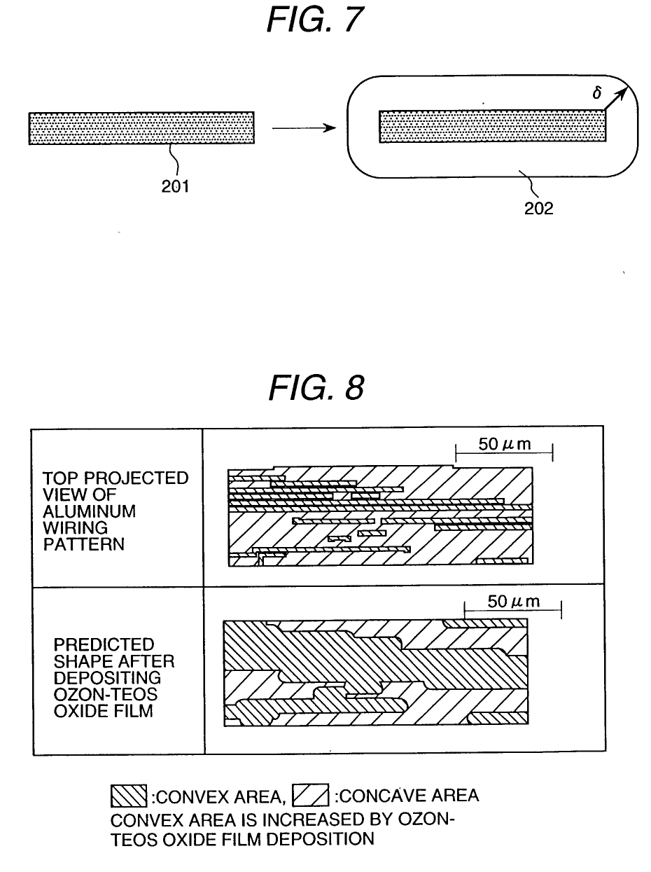

As shown in FIG. 6, there is a characteristic that the ozone-TEOS oxide film 202 is conforamlly formed to a cross-sectional shape of the aluminum wire. Therefore, the area of the convex portion after forming the ozone-TEOS oxide film 202 is expanded larger than the area of the aluminum wiring layer 201 itself, as shown in FIG. 7 when it is seen from the upper side. The magnitude of the expanded area δ can be expressed as δ=(π/4)a using a deposited film thickness a (FIG. 6 and FIG. 7).

FIG. 8 is a top plan view showing the aluminum wiring pattern in the semiconductor device circuit and the convex areas after depositing the ozone-TEOS film. In FIG. 8, the dense hatched region indicates the convex area, and a convex portion areal ratio of a region is defined by a ratio occupied by the convex area to the area of the region. By the method having been described above, the convex shape distribution after forming the ozone-TEOS oxide film all over the chip of 7 mm square is calculated.

An area dividing method will be described below. From a test result, the characteristic length Rc of the CMP apparatus used was 0.8 mm. The value of Rc can be experimentally determined by performing CMP polishing by increasing the groove width from μm order to mm order to obtain a groove width at which the polishing rate rapidly decreases. The value Rc is several mm under a condition of a generally used oxide film CMP. In this embodiment, when an area of a circle expressed by the radius Rc is converted to a side length d of a square having the same area, the side length d=Rc√π=1.417 mm. When the chip of 7 mm is directly divided by the square of d=1.417 mm, the quotient is 4 and the remainder is 1.36 mm. Therefore, 7 mm is divided by 5 (divided by 1.4 mm square).

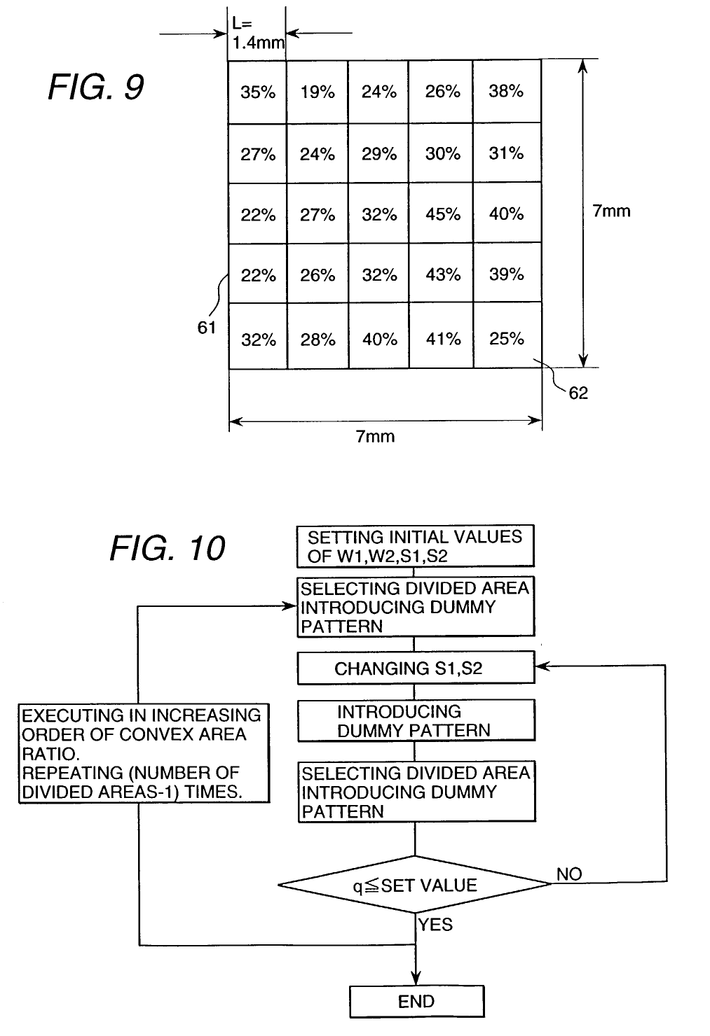

FIG. 9 shows the calculated result of each of the ratios of the convex area (hereinafter, referred to as convex portion areal ratios) with respect to the dividing areas. It can be understood from FIG. 9 that how much the distribution of the convex portion areal ratios is dispersed before introducing the dummy patterns. The maximum convex portion areal ratio is 45%, and the minimum convex portion areal ratio is 22%. Accordingly, the ratio of the both is (maximum)/minimum)=45/22=2.05 times, which results in twice or more difference of the polishing rate. Therefore, the ratios of the convex area of the semiconductor chip in the present embodiment need to be uniformed by introducing the dummy pattern.

FIG. 10 is a flowchart explaining a method of introducing the dummy pattern. An object of introducing the dummy pattern is to increase an areal ratio of an area having a low convex portion areal ratio to reduce the difference between the low convex portion areal ratio and a high convex portion areal ratio. In order to reduce an amount of introduced dummy patterns, the dummy pattern is not introduced into the area having the maximum areal ratio. There, since the maximum value of the areal ratio is 45%, the dummy patterns are introduced so that the convex portion areal ratio of each of the areas approaches to 45%. The method will be described below. Processing of introducing the dummy patterns is successively executed starting from a divided area having the lowest areal ratio.

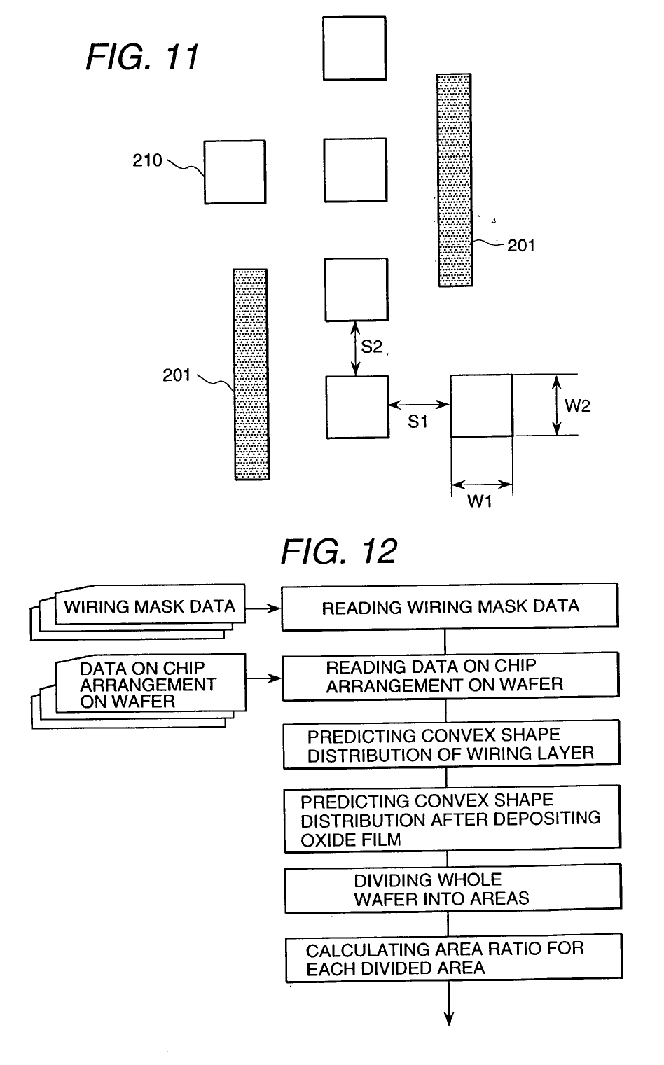

FIG. 11 is a schematic diagram showing the rule introducing the dummy pattern onto the surface of the semiconductor element. The dummy pattern 210 is a square pattern of width W1 [μm] and length W2 [μm], and a plurality of the dummy patterns are periodically arranged in a S1 [μm] spacing in the transverse direction and in a S2 [μm] spacing in the longitudinal direction. At that time, no dummy pattern is introduced at a position where a distance between the dummy pattern 210 and the aluminum wire 201 is smaller than S1 [μm] in the transverse direction or S2 [μm] in the longitudinal direction. Here, as a limiting condition in regard to the dummy pattern 210, the values W1 and W2 of the dummy pattern 210 are fixed and the spaces S1 and S2 are varied. That is, a plurality of dummy patterns having smaller S1 and S2 are periodically introduced in a divided area having a lower areal ratio, and a plurality of dummy patterns having larger S1 and S2 are periodically introduced in a divided area having a higher areal ratio. The dummy pattern 210 is a wire unnecessary for the circuit operation, and the width of the dummy pattern is preferably 1.1 to 2 times as wide as the width of the aluminum wire 210.

Initially, dummy patterns 210 of W1=1.0 μm, W2=1.0 μm, S1=1.3 μm and 1.3 μm are introduced into a divided area having the lowest convex portion areal ratio (into the area having the convex portion areal ratio of 19% after depositing the ozone-TEOS film, in FIG. 9). As for the pattern after introducing the dummy patterns 210, the result of the areal ratio after depositing the ozone-TEOS oxide film of 300 nm showed 36%. The ratio q of the maximum value of the convex portion areal ratio of 45% to this value is calculated as 45/36=1.25. When the maximum allowable value of q in the present embodiment is set to 1.10, the ratio 1.25 does not satisfy the set value. Therefore, the trial calculation is repeated by decreasing the values S1 and S2 until the ratio satisfies the condition q=1.10. As the result of the trial calculation, q=1.097 is obtained when S1=0.9 μm and 0.8 μm, and the condition q<1.10 could be satisfied.

Next, the above-described calculation is executed to the area having the second lowest areal ratio. Since the values W1 and W2 are already determined for the area having the lowest convex portion areal ratio, these value are used as the initial values. This cycle is repeated once for the total number of the divided areas to determine the values S1 and S2 (S1, S2, W1 and W2 when the values W1 and W2 are not fixed) for all the areas except the area having the maximum areal ratio.

As the result of introducing the dummy patterns into all the divided areas in the present embodiment, the value of the maximum/the minimum of the convex portion areal ratios became 1.09. It was confirmed by a test that in the case of introducing the dummy patterns, the ozone-TEOS film polishing height difference (the range between the maximum height and the minimum height) in a chip could be suppressed below ±1.5 nm (except the chips in the wafer edge portion).

On the contrary, in a case where no dummy patterns were introduced, the ozone-TEOS film polishing height difference became ±55 nm. In a case where dummy patterns having the same size and the same spaces were simply introduced, the ozone-TEOS film polishing height difference became ±27 nm. Further, in the present embodiment, the total amount of introduced dummy patterns could be reduced to 35% on the areal ratio compared to the case where dummy patterns having the same size and the same spaces were simply introduced. Furthermore, the total amount of introduced dummy patterns could be reduced to 40% and the polishing time could be suppressed to 60% with keeping the same flatness compared to a case where the dummy patterns were introduced by the method disclosed in the published reference (1).

As described above, according to the present embodiment, the flatness after the CMP polishing can be improved, and the processing time expended for the development and the manufacturing can be reduced. Further, since the dummy pattern is optimized for each chip, the man-power necessary for the calculation processing can be reduced compared to a case where the dummy pattern is optimized over the areas of all the semiconductor devices.

(Embodiment 4)

Description will be made below on a method of optimizing the dummy pattern for the whole wafer having semiconductor chips formed thereon in the embodiment 1 not for one chip, referring to the flowchart of FIG. 12.

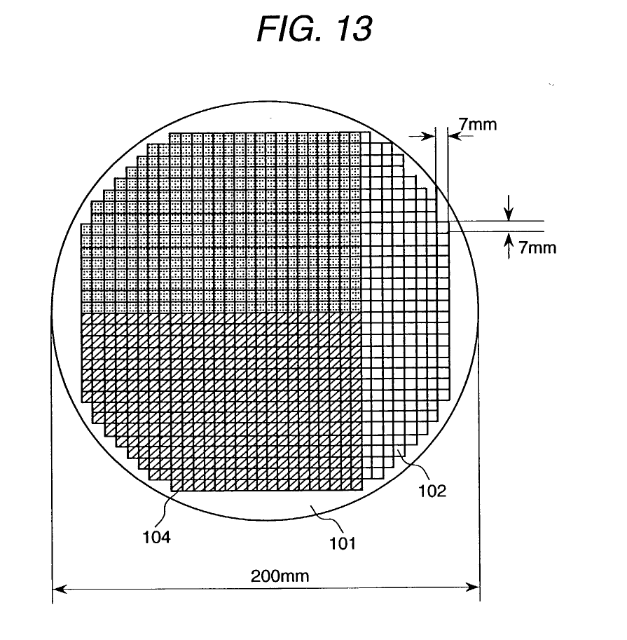

There, the object to be polished is a wafer 101 of 200 mm diameter shown in FIG. 13, and different kinds of semiconductor chips 102, 103 and 104 of 7 mm square are spread all over the wafer 101 to be exposed. The layer to be polished is an ozone-TEOS (tetra ethyl ortho silicate) oxide film formed on an aluminum wiring layer.

In the case of forming the ozone-TEOS oxide film on the aluminum wiring layer, calculation processing on what convex shape distribution appears is initially executed. First, a convex shape distribution of the aluminum layer over the whole wafer is calculated by reading mask data on the aluminum wiring layer and then reading chip arrangement data on the wafer. Next, a convex shape distribution after depositing the ozone-TEOS oxide film on the aluminum wiring layer is calculated over the whole wafer.

An area dividing method will be described below. From a test result, the characteristic length Rc of the CMP apparatus used was 0.8 mm. In this embodiment, when an area of a circle expressed by the radius Rc is converted to a side length d of a square having the same area, the side length d=Rc√π=1.417 mm. As the result of dividing the wafer using this length d and calculating the convex portion areal ratio for each of the divided areas, the maximum value was 48% and the lowest value was 2% in the edge portion of the wafer.

A method of introducing the dummy patterns will be described below, referring to the above-described flowchart of FIG. 10. There, since the maximum value of the areal ratio is 48%, the dummy patterns are introduced so that the convex portion areal ratio of each of the areas approaches to 48%. The method will be described below. Processing of introducing the dummy patterns is successively executed starting from a divided area having the lowest areal ratio.

In the present embodiment, the dummy patterns are also formed according to the rule introducing the dummy pattern shown in FIG. 11. The dummy pattern 210 is a rectangular pattern of width W1 [μm] and length W2 [μm], and the dummy patterns are periodically arranged in a S1 [μm] spacing in the transverse direction and in a S2 [μm] spacing in the longitudinal direction. At that time, no dummy pattern is introduced at a position where a distance between the dummy pattern 210 and the aluminum wire 201 is smaller than S1 [μm] in the transverse direction or S2 [μm] in the longitudinal direction. Here, as a limiting condition in regard to the dummy pattern 210, the values W1 and W2 of the dummy pattern 210 are fixed and the spaces S1 and S2 are varied. That is, a plurality of dummy patterns having smaller S1 and S2 are periodically introduced in a divided area having a lower areal ratio, and a plurality of dummy patterns having larger S1 and S2 are periodically introduced in a divided area having a higher areal ratio.

Initially, dummy patterns 210 of W1=1.0 μm, W2=1.0 μm, S1=1.5 μm and 1.5 μm are introduced into a divided area having the lowest convex portion areal ratio (into the area having the convex portion areal ratio of 2% after depositing the ozone-TEOS film). As for the pattern after introducing the dummy patterns 210, the result of the areal ratio after depositing the ozone-TEOS oxide film of 300 nm showed 35%. The ratio q of the maximum value of the convex portion areal ratio of 48% to this value is calculated as 45/35=1.29. When the maximum allowable value of q in the present embodiment is set to 1.15, the ratio 1.29 does not satisfy the set value. Therefore, the trial calculation is repeated by decreasing the values S1 and S2 until the ratio satisfies the condition q=1.10. As the result of the trial calculation, q=1.090 is obtained when S1=1.12 μm and 1.12 μm, and the condition q<1.15 could be satisfied.

Next, the above-described calculation is executed to the area having the second lowest areal ratio. Since the values W1 and W2 are already determined for the area having the lowest convex portion areal ratio, these value are used as the initial values. This cycle is repeated once for the total number of the divided areas to determine the values S1 and S2 (S1, S2, W1 and W2 when the values W1 and W2 are not fixed) for all the areas except the area having the maximum areal ratio.

As the result of introducing the dummy patterns into all the divided areas in the present embodiment, the value of the maximum/the minimum of the convex portion areal ratios became 1.14. It was confirmed by a test that in the case of introducing the dummy patterns, the ozone-TEOS film polishing height difference (the range between the maximum height and the minimum height) in a chip could be suppressed below ±1.7 nm. On the contrary, in a case where no dummy patterns were introduced, the ozone-TEOS film polishing height difference became ±75 nm. In a case where dummy patterns having the same size and the same spaces were simply introduced, the ozone-TEOS film polishing height difference became ±35 nm. Further, in the present embodiment, the polished height difference of the chip in the edge portion of the wafer could be suppressed to ±22 nm whereas the polished height difference of the chip in the edge portion of the wafer in the previous embodiment was ±22 nm.

As described above, according to the present embodiment, the polishing uniformity of chips existing in the edge portion of the wafer can be improved, and the polishing uniformity can be improved even in a case where plural kinds of chips exist together in the wafer.

(Embodiment 5)

Description will be made below on the case where the size L [mm] of the dividing area in the above embodiment is set to 0.5 mm to 5.5 mm.

It is preferable that the size L of the dividing area is a value smaller than d (=Rc√) obtained from Rc. Since the value Rc is approximately 1 mm to 3 mm in the general CPM polishing condition, d becomes a value 0.9 to 5.3. Since it is necessary for flatting to satisfy the condition L<d, the necessary condition for L is 0.5 mm to 5.5 mm.

From a series of tests changing the hardness of the pad used for CMP and varying Rc=1, 2 and 3 mm, it was clarified that the size L of the dividing area needed to be smaller than 1.2 mm, 3.8 mm and 5.8 mm, respectively. It is considered that Rc=1 mm is a lower limit value under a practically usable CMP condition, and it is preferable that the size L of the dividing area is set to a value smaller than 1.2 mm when Rc can not experimentally obtained or when Rc is unknown.

As described above, the flatting effect can be obtained by setting L to a value larger than 0.5 mm and smaller than 5.5 mm.

(Embodiment 6)

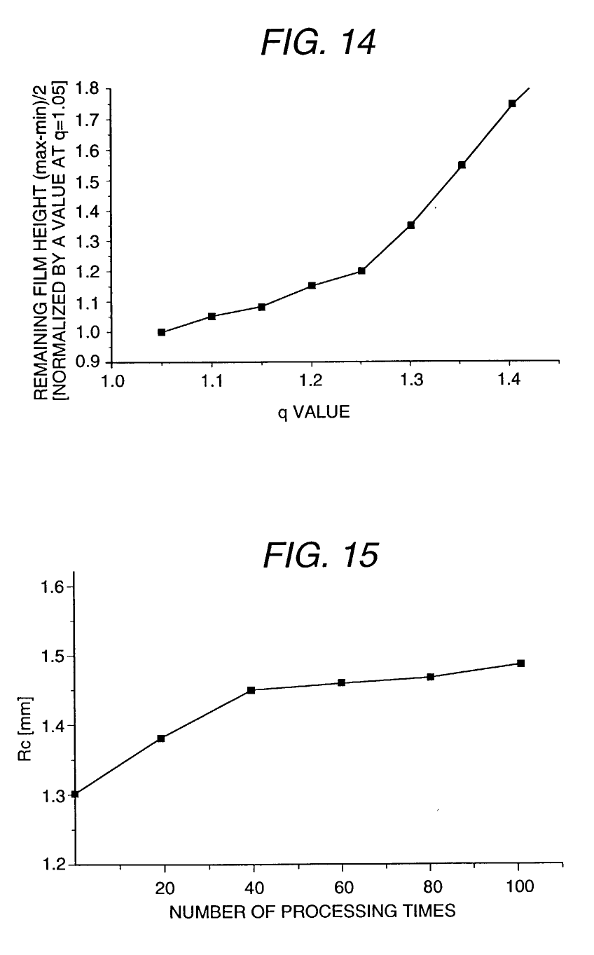

In the present embodiment, description will be made in a case where the value q of the ratio (the maximum value of area of the convex area among the virtual dividing areas)/(area of the convex area of each of the virtual divided areas) is set to a value smaller than 1.3. The value q is a ratio of the convex portion areal ratios which is nearly equivalent to (the maximum of polishing rate)/(the minimum value of polishing rate). Therefore, the flatness after polishing can be increased as the value q is close to 1 (one). As shown in FIG. 14, it was clarified from a test result of an ozone-TEOS oxide film that the flatness was rapidly deteriorated when q exceeded 1.3. Therefore, by setting q to a value smaller than 1.3, the effect of introducing the dummy patterns is made effective to maintain the flatness. Particularly, it is preferable to set q to a value within 1.0 to 1.25.

(Embodiment 7)

In a case where the dividing areas is changed to a rectangle having a longer side of M [mm] and a shorter side of N [mm] from the square in the embodiments, the same effect as that in the embodiment 1 can be obtained. In this case, to is preferable that the value of the longer side N [mm] satisfies the condition of N [mm]<d [mm]. Further, it is preferable that the ratio N/M of the ratio of the shorter side M [mm] to the longer side N [mm] is set to a value larger than ½. By doing so, the area can be avoided to be unnecessarily subdivided too small.

(Embodiment 8)

Description will be made below on a case where a plurality of wafers are successively single-wafer processed using a single chemical mechanical polishing apparatus by varying the value L [mm] wafer by wafer of the plurality of wafers in the embodiments 1 to 5.

The value Rc is increased (or decreased) while the CMP processing is repeated using a single CMP polishing pad. FIG. 15 is a graph showing plots between number of processing times and values Rc experimentally obtained in an oxide film CMP processing apparatus. Corresponding to this result, introducing of dummy patterns was performed by setting the value L to 2.2, 2.5 and 2.7 mm corresponding to the ranges in regard to number of the processing times of 1 to 20, 21 to 40 and above 40, respectively. As the result, it was possible to always maintain good flatness of the polishing height difference below ±17 nm.

As described above, high flatness can be maintained regardless of number of processing times by varying the value L corresponding to the number of processing times.

According to the present invention, the flatness after the CMP processing can be substantially improved by inserting the necessary and minimum amount of dummy pattern. Further, since the inserting amount of the dummy pattern can be suppressed, the cost and the throughput expended for development and manufacture can be improved compared to the case of using the dummy pattern inserting method of prior art.

What is claimed is:

1. A semiconductor device of which an insulation layer covering wiring formed on a surface of a semiconductor element is flattened through a chemical mechanical polishing method, wherein
said surface of the semiconductor element is virtually divided into a plurality of areas, and said wiring necessary for circuit operation and said wiring unnecessary for said circuit operation are arranged so that differences among ratios occupied by convex areas or by concave areas in the individual virtual divided areas may be smaller than 10%.

2. A semiconductor device of which an insulation layer covering wiring formed on a surface of a semiconductor element is flattened through a chemical mechanical polishing method, wherein
said surface of the semiconductor element is virtually divided into a plurality of areas, and said wiring necessary for circuit operation and said wiring unnecessary for said circuit operation are arranged so that a ratio of the maximum value to the minimum value among ratios occupied by convex areas or by concave areas in the individual virtual divided areas may be smaller than 1.3.

3. A semiconductor device of which an insulation layer covering wiring formed on a surface of a semiconductor element is flattened through a chemical mechanical polishing method, wherein
said surface of the semiconductor element is virtually divided into a plurality of areas, and said wiring necessary for circuit operation and said wiring unnecessary for said circuit operation are arranged so that differences between the maximum height and the minimum height after said chemical mechanical polishing in the individual virtual divided areas may be smaller than 30 nm.

4. A semiconductor device of which an insulation layer covering wiring formed on a surface of a semiconductor element is flattened through a chemical mechanical polishing method, wherein
said surface of the semiconductor element is virtually divided into a plurality of areas, and said wiring necessary for circuit operation and said wiring unnecessary for said circuit operation are arranged so as to satisfy at least two out of conditions that differences among ratios occupied by the wiring areas or by the non-wiring areas in the individual virtual divided areas may be smaller than 10%, and that a ratio of the maximum value to the minimum value among said ratios occupied by the wiring areas or by the non-wiring areas in the individual virtual divided areas may be smaller than 1.3, and that a difference between the maximum height and the minimum height after said chemical mechanical polishing in each of the virtual divided areas may be smaller than 30 nm.

5. A method of manufacturing a semiconductor device of which an insulation layer covering wires formed on a surface of a semiconductor element is flattened through a chemical mechanical polishing method, the method comprising the steps of:
virtually dividing said surface of the semiconductor element into a plurality of areas;
calculating ratios of area occupied by convex areas or by a concave areas in the individual virtual divided areas; and
forming said wires necessary for circuit operation and said wires unnecessary for said circuit operation based on at least one out of differences among said ratios of area, and a ratio of the maximum value to the minimum value among said ratios of area occupied by the convex areas or by the concave areas, and a difference between the maximum height and the minimum height after said chemical mechanical polishing in each of the virtual divided areas.

6. A method of manufacturing a semiconductor device of which an insulation layer covering wiring formed on a surface of a semiconductor element is flattened through a chemical mechanical polishing method, the method comprising the steps of:
virtually dividing said surface of the semiconductor element into a plurality of areas, and
forming said wiring necessary for circuit operation and said wiring unnecessary for said circuit operation on the surface of said semiconductor element so as to satisfy at least one out of conditions that differences among ratios occupied by convex areas or by concave areas in the individual virtual divided areas may be smaller than 10%, and that a ratio of the maximum value to the minimum value among said ratios occupied by the convex areas or by the concave areas in the individual virtual divided areas may be smaller than 1.3, and that a difference between the maximum height and the minimum height after said chemical mechanical polishing in each of the virtual divided areas may be smaller than 30 nm.

7. A method of manufacturing a semiconductor device according to any one of claims 5 and 6, wherein
said surface of the semiconductor element is made of a single material, and
an area of said virtual divided area is made equal to an area of a circle expressed by a radius Rc by polishing a substrate, on which a plurality of line-shaped grooves having a width A are engraved with a gap B between the grooves, through said chemical mechanical polishing method, where said Rc is a value of said B when a polishing rate becomes ½ of the maximum polishing rate obtained by varying magnitudes of said A and B while a ratio of said A/B is being kept constant.

8. A method of manufacturing a semiconductor device according to any one of claims 5 to 7, the method comprising the steps of:
virtually dividing said surface of the semiconductor element into square areas having a side length L smaller than said Rc×√;
calculating ratios of convex areas on said surface of the semiconductor element in the individual virtual divided areas; and
forming said wiring necessary for said circuit operation different from said virtual divided area to said virtual divided area and said wiring unnecessary for said circuit operation so that a value of the maximum value of said ratio occupied by the convex areas divided by said ratio occupied by the convex areas in the individual virtual divided areas may be smaller than 1.3.

9. A method of manufacturing a semiconductor device according to any one of claims 5 to 8, wherein said semiconductor element is a semiconductor element formed on a wafer.

10. A method of manufacturing a semiconductor device according to claim 8, wherein said virtual divided area is a square area having said value L within a range of 0.5 mm to 5.0 mm.

11. A method of manufacturing a semiconductor device according to any one of claims 5 to 10, said virtual divided area is square or rectangular.

12. A method of manufacturing a semiconductor device according to any one of claims 5 to 11, wherein when a plurality of wafers are successively single-wafer processed using a single chemical mechanical polishing apparatus, said value L is varied wafer by wafer of said plurality of wafers.
